(19) United States
(12) Patent Application Publication
(10) Pub. No.: US 2014/0264335 A1
(43) Pub. Date: Sep. 18, 2014

(54) PACKAGE SUBSTRATE AND METHOD FOR TESTING THE SAME

(71) Applicant: UNIMICRON TECHNOLOGY CORPORATION, Taoyuan (TW)

(72) Inventors: Dyi-Chung Hu, Taoyuan (TW); Tsung-Si Wang, Taoyuan (TW); Jui-Yang Ma, Taoyuan (TW)

(73) Assignee: UNIMICRON TECHNOLOGY CORPORATION, Taoyuan (TW)

(21) Appl. No.: 13/845,800

(22) Filed: Mar. 18, 2013

(51) Int. Cl. H01L 21/66

(52) U.S. Cl. CPC H01L 22/30; H01L 22/14
USPC 257/48; 438/18

(57) ABSTRACT

A package substrate is provided, including a board body having a wiring region and a testing region defined thereon, conductive pads embedded in the wiring region, and a plurality of testing pads disposed in the testing region and electrically connected to the conductive pads, wherein the top surface area of each of the testing pads is greater than the top surface area of each of the conductive pads in order to facilitate a precise alignment of a probe with a corresponding one of the testing pads and prevent the probe from being blocked by the board body when in electrically testing an embedded circuit.

### BACKGROUND OF THE INVENTION

1. Field of the Invention

The present invention relates to package substrates, and, more particularly, to a package substrate and a method for testing the same.

2. Description of Related Art

With the development of the electronic industry, electronic products gradually trend toward a light, thin and compact design. For example, the wiring density of a package substrate carrying electronic elements increases significantly to facilitate minimizing and thinning an electronic product. Therefore, in order to meet the need of a high density circuit, a technique for embedding circuits in a substrate is thus developed. FIG. 1A is a schematic top view of a package substrate 1 according to the prior art.

As shown in FIG. 1A, the package substrate 1 comprises a board body 10 and a plurality of circuits 11 embedded in the board body 10. The board body 10 carries a semiconductor component (not shown), the circuit 11 has wires 110 and conductive pads 111 connected to the wires 110, and the conductive pads 111 electrically connect to the semiconductor component.

In general, before a semiconductor component is disposed on or electrically connected to a package substrate, the circuit 11 should be under a test to check whether the circuit 11 is well electrically connected. As shown in FIG. 1B, a testing element such as a probe 3 contacts to each of the conductive pads 111 such that the probe 3 electrically connects to the conductive pads 111 to test the circuit 11.

In the electrical test for a prior embedded circuit 11 as shown in FIG. 1B′, because the circuit 11 depresses at a surface of the board body 10, the probe 3 has to precisely align to the conductive pad 111. Otherwise, a difference, if occurs, would cause the probe 3 to be blocked by the board body 10 and thus cannot contact the conductive pad 111.

However, with electronic products gradually trending toward a light, thin and compact design, circuits 11 of a prior package substrate 1 should meet the need of fine circuits and fine pitches. For this needs, when performing an electrical test for the circuit 11, because the top surface area of the conductive pad 111 is too small to allow the probe 3 to precisely align to the conductive pad 111, the probe 3 is apt to be blocked by the board body 10 to contact the conductive pad 111, and thus this significantly decreases the accuracy of the test.

Moreover, if the density of each circuit 11 is increased, that is, the spacing s between adjacent circuits 11 is extremely small. If the spacing is less than 30 μm, since existing testing equipments can only test the spacing greater than 30 μm between the circuits 11, when the probe 3 tests circuits 11 having a pitch finer than 30 μm, the probe 3 cannot be precisely placed on the conductive pad 111. Therefore, this not only results in an inaccurate test result, but also prevents the package substrate from developing toward fine circuits and fine pitches, causing increased difficulty and equipment cost of the test.

Therefore, presently how to overcome the mentioned problems of the prior art is substantially an issue desirably to be solved.

### SUMMARY OF THE INVENTION

In view of the above-mentioned problems of the prior art, the present invention provides a package substrate, comprising: a board body having a wiring region and a testing region defined thereon, at least one conductive pad disposed in the wiring region of the board body, and a plurality of testing pads disposed in the testing region of the board body and electrically connected to the conductive pad, wherein the top surface area of each of the testing pads is greater than that of the conductive pad.

In an embodiment, the wiring region surrounds the testing region or is disposed in an interior region of the testing region.

In an embodiment, the conductive pads are spaced apart at a first interval that is less than a second interval at which any two of the testing pads are spaced apart and is less than a third interval at which any one of the conductive pads is spaced apart from any one of the testing pads.

In an embodiment, the testing pad is electrically connected to the conductive pad via a lead, and the testing pad is embedded in the testing region or exposed from a surface of a dielectric layer of the testing region.

In an embodiment, the conductive pad is connected to a wire such that the conductive pad and the wire form a circuit disposed in the wiring region of the board body, and an impedance matching structure is connected between the testing pad and the circuit.

In an embodiment, the conductive pad is embedded in the wiring region of the board body.

The present invention further provides a method for testing the package substrate, including electrically connecting a testing element to the testing pads to test each of the circuits.

In an embodiment, the testing element is a probe, and the top surface area of the probe is less than that of the testing pad and is greater than that of the conductive pad.

It is known from above that the package substrate and method for testing the package substrate according to the present invention dispose a plurality of testing pads having a greater top surface area than that of the conductive pads in regions outside the wiring region such as an open area. Therefore, the disposal of the conductive pad (or the circuit) is not affected, and the probe is allowed to precisely align to the testing pad when performing a circuit test.

Furthermore, when the conductive pad or circuit has a very high density, because the probe contacts to a testing pad with a greater top surface area to perform a test, the accuracy of the testing result is remained, which allows the test to be readily completed and thus facilitates the package substrate developing toward to fine circuits and fine pitches.

### BRIEF DESCRIPTION OF DRAWINGS

The invention can be more fully understood by reading the following detailed description of the preferred embodiments, with reference made to the accompanying drawings, wherein:

FIGS. 1A and 1B are schematic top views illustrating a method for testing a package substrate according to the prior art, wherein FIG. 1B′ is a cross-sectional view of FIG. 1B;

FIGS. 2A and 2B are schematic top views illustrating a method for testing a package substrate according to the present invention, wherein FIG. 2B′ is a cross-sectional view of FIG. 2B;

FIGS. 3 and 4 are local schematic top views of other different embodiments of a package substrate according to the present invention; and

FIG. 5 is another embodiment of FIG. 2A.

### DETAILED DESCRIPTION OF THE INVENTION

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

It should be advised that the structure, ratio, and size as illustrated in this context are only used for disclosures of this specification, provided for persons skilled in the art to understand and read, and technically do not have substantial meaning. Any modification of the structure, change of the ratio relation, or adjustment of the size should be involved in the scope of disclosures in this specification without influencing the producible efficacy and the achievable objective of this specification. Also, the referred terms such as “on”, “top” and “one” in this specification are only for the convenience to describe, not for limiting the scope of embodiment in the present invention. Those changes or adjustments of relative relationship without substantial change of technical content should also be considered within the category of implementation.

FIGS. 2A and 2B are schematic top views illustrating a method for testing a package substrate according to the present invention.

As shown in FIG. 2A, a package substrate 2 is provided, comprising a board body 20 having a wiring region 20a and a testing region 20b (the area enclosed by dashed lines) defined thereon, a plurality of circuits 21 embedded in the wiring region 20a, and a plurality of testing pads 220 disposed in the testing region 20b.

The board body 20 carries a semiconductor element (not shown), and a dielectric layer is formed on the board body 20, for the circuits 21 to be disposed thereon.

The circuits 21 has wires 210 and conductive pads 211 connected to the wires 210, and the conductive pads 211 are used for electrically connecting to the semiconductor component by a wire bonding method. The number and size of the conductive pads 211 should accord to the number and size of contacts of the semiconductor component.

The testing pad 220 are electrically connected to the conductive pad 211, and the top surface area of the testing pad 220 is greater than that of the conductive pad 211.

In an embodiment, the wiring region 20a surrounds the testing region 20b, and the testing pad 220 is embedded in the testing region 20b surface. Therefore, the circuit 21 and the testing pad 220 are formed together. In another embodiment, the testing pads 220 are disposed on a dielectric surface of the testing region 20b. For example, a process is performed with an existing package substrate, and the circuit 21 and the testing pad 220 are formed, respectively.

Moreover, the circuit 21 is an outmost circuit layer of the package substrate 2, and the internal structure of the package substrate 2 has various patterns which are not limited.

Further, the testing pads 220 are electrically connected to the conductive pads 211 via leads 221. The testing pad 220 and the lead 221 form a portion of extension 22. If the testing pads 220 are disposed in the testing region 20b surface, the lead 221 will cover on the conductive pad 211. In other embodiments, the testing pads 220 are electrically connected to the conductive pads 211 by a wire bonding method (i.e., by a bonding wire) or other methods.

In addition, the top surfaces of the testing pads 220 are circular but are not limited thereto.

As shown in FIGS. 2B and 2B′, a testing element is utilized to contact each of the testing pads 220 such that the testing element electrically connects to the testing pads 220 to test each of the circuits 21.

In an embodiments, the testing element is a probe 3, wherein the top surface area D of the probe 3 is less than the top surface area R of the testing pad 220, and the top surface area D of the probe 3 is greater than the top surface area W of the conductive pad 211. For example, the top surface area R of the testing pad 220 is greater than the sum of the top surface area D of the probe 3 and the alignment error.

The package substrate 2 according to the present invention utilizes an open area outside the wiring region 20a as a testing region 20b for disposing a testing pad 220 such that the testing pad 220 replaces the conductive pad 211 to be a contact of a test. Thus, when performing the test of the circuit 21, the probe 3 is placed on a testing pad 220 having a greater top surface area R for testing, this not only allows the probe 3 to readily align and contact, but also prevent the test from being blocked by the board body in the prior art.

Moreover, the testing pads 220 are disposed on the open area, and thus would not effect the disposal of the circuit 21. The design of the circuit 21 satisfies the demands for fine circuits and fine pitches, specifically, as shown in FIG. 3.

FIG. 3 is a local schematic top view of another embodiment of FIG. 2. The composition and operation principle of a package substrate 2′ of this embodiment are generally identical with those of the embodiment of FIG. 2, and thus the identical part thereof is omitted.

In this embodiment, the testing pad 220′ and the conductive pad 211′ are rectangular copper blocks, and the spacing t between any two of the conductive pads 211′ (or the spacing between any two of the circuit bodies 210) is less than the spacing L between any two of the testing pads 220′ and the spacing L′ between the conductive pad 211′ and the testing pad 220′. For example, the spacing t between any two of the conductive pads 211′ (or the spacing between any two of the circuit bodies 210) is less than 30 μm, and the spacing L between any two of the testing pads 220′ is greater than 30 μm, and the spacing L′ between the conductive pad 211′ and the testing pad 220′ is greater than 30 μm.

The present invention utilizes an open area of the board body 20 (i.e., the testing region 20b) to dispose the testing pads 200 to design a contact with a greater top surface area. Pitches of the testing pads 220 are greater than 30 μm such that the structures of fine circuits and fine pitches (wherein the pitches of the circuit 21 is less than 30 μm) are able to perform electrical tests. Therefore, the probe 3 of existing equipments can be precisely placed on the testing pad 220, this not only obtains an accurate test result and readily completes the test, but also significantly decreases the manufacturing cost of a package substrate 2, which is advantageous for the package substrate 2 developing toward fine circuits and fine pitches.

In addition, each of the testing pads 220, 220′ is electrically connected to the conductive pad 211′ via the lead 221. Considering the length of the lead 221 and the size of the testing pad 220, 220′ influence the resistance in an electrical test, an impedance matching structure 24 is designed between the testing pad 220″ and the conductive pad 211′ to obtain a more accurate resistance in the electrical test as shown in FIG. 4. Specifically, the length of the lead 211″ is shortened and the area of the testing pad 220″ is reduced.

FIG. 5 is another embodiment of FIG. 2A. In the package substrate shown in FIG. 5, the wiring region 50a is disposed in an interior region of the testing region 50b. In this embodiment, the conductive pads 511 electrically connect to the semiconductor component by a flip-chip method, so a wire (not illustrated) is whether disposed in the wiring region 50a or not depending on the need.

In the above embodiments, the conductive pads 211, 511 (or circuits 21) may also be disposed on the surface of the wiring region 20a, 50a.

In summary, the package substrate and testing method thereof of the present invention utilizes an open area of the board body to separately design a testing pad for an electrical test. The testing pad is connected to the conductive pad to increase the top surface area of the testing pad in a wiring design for providing a required alignment error to a testing equipment, and thus an existing equipment can be applied to achieve the electrical test for an embedded circuit.

Further, the package substrate performs a circuit test with patterns of various fine circuits and fine pitches such as 30 μm, 20 μm, 10 μm and similar, and thus is advantageous for the package substrate developing toward fine circuits and fine pitches.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A package substrate, comprising:
a board body having a wiring region and a testing region defined thereon;
a plurality of conductive pads disposed in the wiring region of the board body; and
a plurality of testing pads disposed in the testing region of the board body and electrically connected to the conductive pads, wherein each of the testing pads has a top surface area greater than a top surface area of each of the conductive pads.

2. The package substrate of claim 1, wherein the wiring region surrounds the testing region.

3. The package substrate of claim 1, wherein the wiring region is positioned in an interior area of the testing region.

4. The package substrate of claim 1, wherein any two adjacent areas of the conductive pads are spaced apart from each other at a first interval less than a second interval at which any two adjacent areas of the testing pads are spaced apart from each other and further less than a third interval at which any one of the conductive pads is spaced apart from any one of the testing pads.

5. The package substrate of claim 1, further comprising a plurality of leads for electrically connecting the testing pads to the conductive pads.

6. The package substrate of claim 1, wherein the testing pads are embedded in the testing region.

7. The package substrate of claim 1, further comprising a dielectric layer with the testing pad exposed therefrom.

8. The package substrate of claim 1, further comprising a plurality of wires connected to the conductive pads, wherein the conductive pads and the wires form a circuit positioned in the wiring region of the board body.

9. The package substrate of claim 8, further comprising an impedance matching structure connected between the testing pads and the circuit.

10. The package substrate of claim 1, wherein the conductive pads are embedded in the wiring region of the board body.

11. A method for testing a package substrate, comprising:
providing a package substrate of claim 1; and
electrically connecting a testing element to the testing pads and the conductive pads.

12. The method of claim 11, wherein any two adjacent areas of the conductive pads are spaced apart from each other at a first interval less than a second interval at which any two adjacent areas of the testing pads are spaced apart from each other and a third interval at which any one of the conductive pads is spaced apart from any one of the testing pads.

13. The method of claim 11, wherein the testing pads are electrically connected to the conductive pads via a plurality of leads.

14. The method of claim 11, wherein the conductive pads are connected to a plurality of wires, such that the conductive pad and the wire form a circuit positioned in the wiring region of the board body.

15. The method of claim 14, wherein the testing pads are connected to the circuits via an impedance matching structure.

16. The method of claim 11, wherein the conductive pads are embedded in the wiring region of the board body.

17. The method of claim 11, wherein the testing element is a probe.

18. The method of claim 17, wherein the probe has a top surface area that is less than a top surface area of each of the testing pads and is greater than a top surface area of each of the conductive pads.
